(19) United States
(12) Patent Application Publication
(10) Pub. No.: US 2006/0008594 A1
(43) Pub. Date: Jan. 12, 2006

(54) Plasma enhanced chemical vapor deposition system for forming carbon nanotubes

(76) Inventors: Sung Gu Kang, San Jose, CA (US); Woo Kyung Bae, Campbell, CA (US)

Correspondence Address: FENWICK & WEST LLP, SILICON VALLEY CENTER, 801 CALIFORNIA STREET, MOUNTAIN VIEW, CA, 94041, US

(21) Appl. No.: 10/889,807

(22) Filed: Jul. 12, 2004

(51) Int. Cl. C23C 16/00

(52) U.S. Cl. 427/569; 118/723 E; 427/585

(57) ABSTRACT

An embodiment of a system for forming carbon nanotubes (CNTs) using plasma enhanced chemical vapor deposition (PECVD) uses one or more of RF and DC power supplies coupled to electrodes in various configurations within a process chamber of the system. By application of a sufficient DC voltage to one or more electrodes, the system allows for growing CNTs that can be straighter and have improved electrical performance characteristics.

### BACKGROUND

### FIELD OF THE INVENTION

This invention relates generally to systems for forming carbon nanotubes, and in particular to forming carbon nanotubes using plasma enhanced chemical vapor deposition (PEVCD).

### BACKGROUND OF THE INVENTION

Growing carbon nanotubes (CNTs), such as those suitable for use in electron emissive applications, generally involves two reactions: The first is disassociating, or decomposing, a hydrocarbon gas to generate carbon atoms and ions, and the second is causing the absorption of carbon atoms by a catalytic material to supersaturation to cause the precipitating effects that result in carbon nanotubular growth. Each of these reactions typically requires an energy source or other mechanism to deliver the energy required for the chemical reaction. Generally following these principles, there are distinct methods commonly used for growing CNTs, including arc discharging, laser ablation, and chemical vapor deposition (CVD).

In arc discharging processes, two electrodes are used. One electrode, equipped with a power supply, is formed of or contains graphite. When the power supply is turned on, vaporized graphite in the form of composites of carbon are attracted to or are grown on the opposite electrode. Laser ablation is similar to arc discharging, but instead of an electrical arc to invoke or instigate the vaporization of the graphite material of the electrode, a laser is used to impinge upon a volume of feedstock gases to achieve the same results.

Within CVD, there are various types of CVD processes, including thermal CVD and plasma enhanced chemical vapor deposition (PECVD). In thermal CVD processes, a single energy source produces high temperatures to cause both reactions involved in CNT growth, as described above. In typical PECVD systems, however, radio frequency (RF) energy is used to assist in the disassociation reaction with the source hydrocarbon gas to generate the necessary carbon ions or radicals. A heated electrode (generally opposite a RF power source linked to a top electrode) is used to cause the reaction of the carbon radicals with the catalytic particulates.

Of these processes, the present invention relates to systems that use PECVD to grow CNTs. A significant limitation of existing PECVD-based systems is that they traditionally use only RF power supplies. Although some PECVD systems may have dual electrodes (e.g., top and bottom), and may even have RF supplies to both, none have DC power supplies coupled to them to apply DC power or a combination of RF and DC energy to synthesize CNTs. As a result, the CNTs grown with current methods are often “spaghetti”-like in appearance and have geometries and properties that are less controlled. Due to these deficiencies, existing methods produce lower quality CNTs, which have poor electron emission properties and resulting poor performance.

### SUMMARY OF THE INVENTION

To address the deficiencies of existing methods, a system and tool for forming CNTs using PECVD includes power supplies in addition to the RF power supplies used in traditional PECVD equipment. In one embodiment, in addition to supplying RF power, a PEVCD system includes a DC power supply to cause the growth of CNTs. In other embodiments, one or more each of RF and DC power supplies can be arranged in a number of different configurations (e.g., on bottom and top electrodes). These combinations and the variations for the different power supplies can produce superior CNTs compared with those formed using existing tools and equipment. For example, the CNTs grown with this method and equipment can be straighter and easier to control. Beneficially, straighter CNTs tend to have improved emission properties and characteristics.

### BRIEF DESCRIPTION OF THE DRAWINGS

FIG. 1 illustrates a system for forming carbon nanotubes using PECVD, in accordance with an embodiment of the invention.

### DETAILED DESCRIPTION OF THE PREFERRED EMBODIMENTS

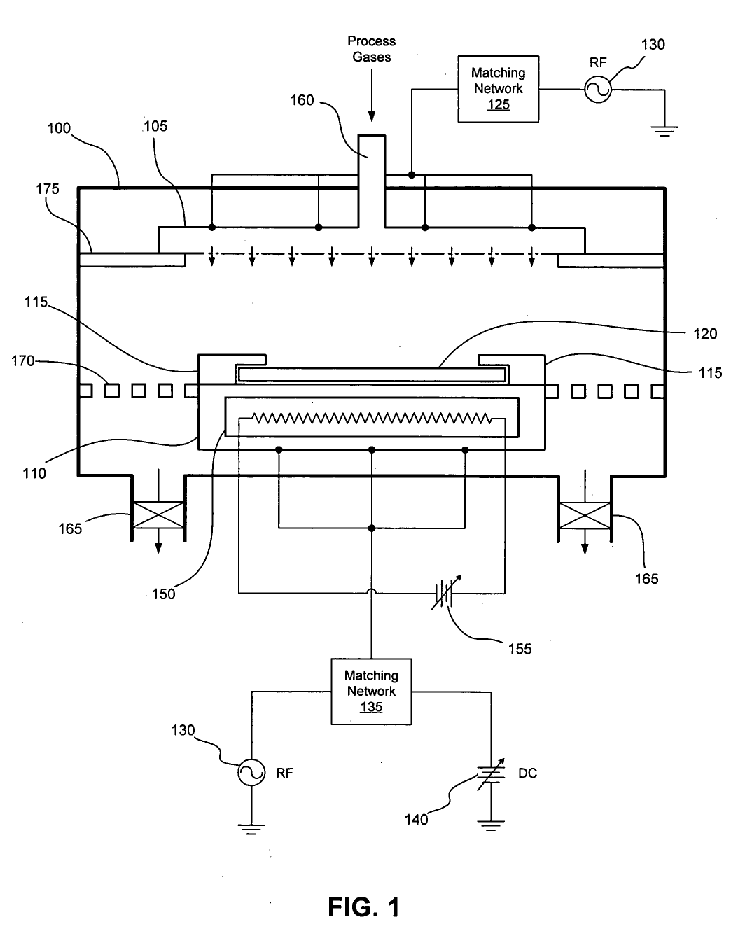

FIG. 1 illustrates a PEVCD system for forming carbon nanotubes using a combination of RF and DC power, in accordance with an embodiment of the invention. The PECVD system comprises a chamber 100 that houses many of the components of the system. In the chamber 100 is an electrode structure for delivering power for the PECVD process. In the embodiment shown in FIG. 1, the electrode structure includes a top electrode 105 and a bottom electrode 110, implemented in this embodiment as a pair of opposing electrode plates. As described in more detail below, these electrodes 105 and 110 are coupled to various power supplies for applying energy to the reactants within the chamber 100 to cause CNT growth. Typically, the CNTs are growth on a target substrate 120. Accordingly, the system further includes a pair of holding plates 115 to secure in place a target substrate 120 on which CNTs are to be grown. However, it can be appreciated that any of a number of mechanical and non-mechanical means can be used to secure a substrate 120 during the PECVD process.

In the embodiment shown in FIG. 1, the top electrode 105 is coupled to a RF power supply 130 via a matching network 125. In another embodiment, the bottom electrode 110 is coupled to a RF power supply 130 and to a DC power supply 140 via a matching network 135. Preferably, the DC and RF power supplies 130 and 140 are coupled to their corresponding electrodes 105 and/or 110 through a plurality of electrical contact points, as shown in the figure. In other embodiments, additional or alternate RF and/or DC power supplies could be coupled to either or both of the top and bottom electrodes 105 and 110, or such power supplies could be coupled to any other electrodes used in the system. Accordingly, a number of different configurations of electrodes and power supplies are encompassed by the scope of the invention.

The matching networks 125 and 135 adjust the impedance between the corresponding RF power supply 130 and the plasma in the reactor chamber 100. Due to possible variation of the impedance of the plasma within the chamber 100, the effect of the applied RF power can be reduced as the process conditions change within the reactor chamber 100. Accordingly, an unmatched impedance factor could have deleterious effects to the processing. The matching network 125 or 135 thus serves to optimize the RF power delivery and avoid power loss.

In one embodiment of the PECVD system, the attached RF power supply 130 is designed to granularize a catalyst material on the target substrate 120. CNTs are often formed on catalyst materials, typically a metal such as nickel, which have been laid down on the substrate 120 and then granularized (e.g., formed into small balls on the substrate 120). Accordingly, the RF power supply 130 is programmed to supply power to its corresponding electrode 105 or 110 during a pre-treatment stage of the CNT growth process, in which the catalyst material is granularized (an example of such a process described below). To perform this function, the RF power supply 130 can supply power sufficient to granularize a catalyst material on the substrate 120. In one embodiment, the RF power supply 130 can supply power within a range of about 0.5 to about 1.5 Watts/cm² and within a frequency range of about 13.56 MHz to about 4 GHz.

In this PECVD system, the DC power supply 140 is designed to cause the synthesis of CNTs on the granularized catalyst material on the target substrate 120. Accordingly, the DC power supply 140 is programmed to supply DC power during a CNT growth phase. Preferably, this DC power, alone or in combination with another energy source, is sufficient to form carbon radicals or ions in a source gas in the chamber 100, thereby causing the carbon to form CNTs on the substrate 120. In one embodiment, the power supplied by the DC power supply 140 is sufficient by itself, without additional applied RF energy, to cause CNT growth under appropriate conditions, such as those described below. In one embodiment, the DC power supply 140 can supply a negative voltage within a range of about 100 to about 1000 V. Alternatively, the DC power supply 140 may have the opposite polarity depending on the configuration or orientation of the electrodes to which it is connected.

The PECVD system further comprises a heating element 150 that can be thermally coupled to a target substrate 120 when the substrate 120 is placed in the chamber 100. The heating element 150 is coupled to a heater power source 155, which supplies a controllable amount of energy to the heating element 150. In one embodiment, the heating element 150 is part of the electrode structure. As shown in FIG. 1, the heating element 150 is within the bottom electrode 110. Because the bottom electrode 110 is configured to support the substrate 120 and is therefore in contact with the substrate 120, heat energy from the heating element 150 is conducted through the bottom electrode 110 to the substrate 120. Alternatively, heat conductive elements may be placed between the substrate 120 and the electrode 110, allowing heat to be conducted from the heating element 150 to the substrate 120. When thermally coupled to the substrate 120, the heating element 150 is capable of raising the substrate 120 to an elevated temperature, which in one embodiment is within a range of about 300 to about 600° C.

To control the gases within the chamber 100, the system further includes mass control and pressure control subsystems. A gas inlet 160 is used to introduce process gases into the reaction chamber 100, such as in the example process described below. The gas inlet 160 can receive one or more different gases used in the PECVD process and control the flow of those gases into the camber 100. Preferably, the gas inlet 160 spreads the process gases over a wide area to provide a gas shower that delivers the gases roughly evenly over a reaction area in the chamber 100. The gas inlet 160 may be coupled to one or a plurality of sources of process gases, using mass controllers or any other suitable means to control the gases introduced into the chamber 100. Moreover, the gas inlet 160 may be made of an electrically conducting material, such as a metal, so its structure can also be used as the top electrode 105, as shown in FIG. 1.

At another end of the chamber 100, a pressure control subsystem 165 controls the pressure of the gases within the chamber 100. The pressure control subsystem 165 may include one or more pumps, valves, flow meters, and other components commonly used in PECVD systems for controlling gas flow and chamber pressure. These pressure control subsystem 165 may be placed at corresponding ports in the chamber 100. In one embodiment, the pressure control subsystem 165 is capable of reducing the pressure in the chamber 100 to a pressure within a range of about 0.1 to about 10 Torr.

A hole plate 170, also called a punching plate, is disposed between the reaction area in the chamber 100 and the pressure control subsystem 165. The hole plate 170 includes a number of holes to allow the gases to escape the chamber 100. One function of the hole plate 170 is to make uniform the flow of the gas during evacuation or exhausting of the chamber 100, both when fully evacuating and during processing. The gas is evacuated or drawn from the chamber 100 by way of the pressure control subsystem 165, using for example turbo pumps. The gas passes through the hole plate 170 and then through exhausting ports of the chamber 100. The hole plate 170 typically comprises a metal cover perforated with many holes. In addition to the function noted above, these holes prevent larger particles from entering and damaging the pump/exhaust systems.

A screen plate 175 at the top of the chamber 100 confines the electrical field from the top electrode 105 to the lower electrode 110. In one embodiment, the screen plate 175 is adjustable to cover different areas of the top electrode 105. Accordingly, the area exposed to or affected by the plasma can be changed or modified by varying the widths of the top electrode 105 that is exposed by the screen plate 175.

Also described herein is one embodiment of a process for forming carbon nanotubes on a substrate using embodiments of the PEVCD system, described above and shown in FIG. 1. It will be appreciated to those of skill in the art that various modifications can be made to this method and to the structure of the tool and system described herein without departing from the scope of the invention. The following patent applications describe processes and equipment for growing or forming carbon nanotubes: U.S. application Ser. No. 10/302,126, filed Nov. 22, 2002, entitled “Method for Forming Carbon Nanotubes”; U.S. application Ser. No. 10/302,206, filed Nov. 22, 2002, entitled “Method for Forming Carbon Nanotubes”; and U.S. application Ser. No. 10/600,226, filed Jun. 19, 2003, entitled “Forming Carbon Nanotubes at Lower Temperatures Suitable for Electron-Emitting Device, and Associated Fabrication Method.” Each of these applications is incorporated by reference in its entirety.

In a pre-formation step, a substrate 120 is loaded into the process chamber 100 of the system. This loading step may be performed manually or using robot handler and arm interface. In one embodiment, before the substrate 120 is placed inside the chamber 100, a holding plate 115 comes up higher than the substrate 120. Loading pins then lower the substrate 120 and the holding plates 115 to a secured position on the bottom electrode 110. The holding plate 115 operates to secure the substrate 120 in position during the formation process. Thereafter, the chamber 100 door is closed, and the inside of the process chamber 100 is isolated from the other parts of the equipment. Although this step of loading is described, the substrate 120 on which CNTs are to be formed can be loaded in any appropriate technique.

Once the substrate 120 is loaded into the chamber 100, a pre-treatment step can be performed. In an example of a pre-treatment step, a catalyst material on the substrate 120 is granularized. The pressure in the process chamber 100 is lowered by the pressure control subsystem 165 to a desired pressure, approaching a vacuum pressure, and the distance between the top and bottom electrodes 105 and 110 is controlled to be a specified distance. In one embodiment, this distance is between about 1 to about 5 cm. The substrate 120 is then heated to process temperatures in the range of about 300 to about 600° C. When the pressure reaches the vacuum pressure level, process gases (e.g., gases comprising ammonia or ammonia mixed with hydrogen) are introduced into the chamber through mass flow controllers and the gas inlet 160, producing a gas shower in the chamber 100. After introducing process gasses into the chamber 100, the pressure is controlled by the pressure control subsystem 165. In one embodiment, this pressure is controlled to be within the range of about 0.1 to about 10 Torr. After the pressure stabilizes at the set value, RF power is turned on at an electrode 105 or 110. In one embodiment, this RF power is in the range of about 0.5 to about 2.0 Watt/cm² and is applied for less than 10 minutes. When the processing time is complete, the applied RF power and gases are turned off, and the gases are pumped out of the process chamber 100.

To initiate synthesis of CNTs on the substrate 120, process gasses are added to the chamber 100. These process gases supply carbon for the CNT growth and may comprise hydrocarbon and ammonia, mixes of hydrogen, or other suitable gases. The pressure in the chamber 100 is controlled by the pressure control subsystem 165, which in one embodiment maintains the pressure within a range of about 0.1 to about 10 Torr. After the pressure in the chamber 100 is stabilized, the substrate 120 is exposed to the process gases, which in one embodiment occurs for less than 10 minutes. The DC power supply 140, coupled to supply DC power to the lower electrode 110, is turned on. In one embodiment, the DC voltage applied to the electrode 110 is in the range of about −100 to about −1000 V and is applied for less than 20 minutes. After the growth is complete, the DC power is turned off and the process gases are pumped out of the chamber 100.

In a post-treatment step, process gasses are again pumped into the chamber. In one embodiment, these process gasses comprise hydrogen or hydrogen mixed with ammonia. The pressure within the chamber 100 is controlled by way of the pressure control subsystem 165. The RF power supply 130 is then turned on. In one embodiment, the RF power supplied is within a range of about 0.5 to about 2.0 Watt/cm² and is applied for less than 20 minutes. After the post-processing is complete, the RF power supply 130 is turned off, and the gases are pumped out of the chamber 100. Preferably, the hardware configuration of the PECVD system used in the post-treatment is consistent with the hardware configuration used in pre-treatment.

Once the CNTs are grown on the substrate 120 and all processing is complete, the holding plates 115 are lifted to allow the substrate 120 to be removed from the chamber 100. The lifting can be performed by loading pins and the substrate 120 retrieved by a robot arm.

As described herein, a PECVD system with DC and RF power supplies allows for forming CNTs with improved properties. In one embodiment, the system comprises a standard PECVD tool that has been modified to have two electrodes (e.g., on the top and bottom) and two power supplies, where a RF power supply is coupled to the top or bottom electrodes, and a DC power supply is coupled to the bottom electrode. Alternative embodiments include any of these power supplies in other configurations (e.g., the DC power supply coupled to the top electrode) and in any combination with various known materials and devices associated with the process of growing CNTs using PECVD.

The foregoing description of the embodiments of the invention has been presented for the purpose of illustration; it is not intended to be exhaustive or to limit the invention to the precise forms disclosed. Persons skilled in the relevant art can appreciate that many modifications and variations are possible in light of the above teachings. It is therefore intended that the scope of the invention be limited not by this detailed description, but rather by the claims appended hereto.

We claim:

1. A plasma enhanced chemical vapor deposition (PECVD) system for forming carbon nanotubes, the system comprising:
a chamber for receiving therein a target substrate on which carbon nanotubes are to be formed;
an electrode structure within the chamber for supplying energy for the formation of carbon nanotubes;
a radio frequency (RF) power supply coupled to the electrode structure to apply energy within the chamber; and
a direct current (DC) power supply coupled to the electrode structure to apply sufficient energy within the chamber to cause synthesis of carbon nanotubes on the target substrate during a PECVD process.

2. The system of claim 1, wherein the electrode structure comprises a pair of opposing electrodes.

3. The system of claim 2, wherein the RF power supply is coupled to a first electrode of the pair of electrodes, and the DC power supply is coupled to a second electrode of the pair of electrodes.

4. The system of claim 3, wherein the RF power supply is further coupled the second electrode.

5. The system of claim 2, wherein the RF power supply is coupled to a first electrode of the pair of electrodes, and a second electrode of the pair of electrodes is electrically grounded.

6. The system of claim 2, wherein the pair of opposing electrodes comprises a top electrode and a bottom electrode.

7. The system of claim 6, wherein the bottom electrode is configured to support the target substrate, the target substrate lying on the bottom electrode.

8. The system of claim 6, wherein the top and bottom electrodes are separated by a distance of about 1 to about 5 cm.

9. The system of claim 1, further comprising:
a heating element coupled to supply heat energy within the chamber.

10. The system of claim 9, wherein the heating element is thermally coupled to an electrode of the electrode structure.

11. The system of claim 9, wherein the heating element comprises an electrode of the electrode structure.

12. The system of claim 9, wherein the heating element is capable of raising an electrode of the electrode structure to a temperature within a range of about 300 to about 600° C.

13. The system of claim 1, wherein the DC power supply is programmed to supply power during a carbon nanotube growth phase.

14. The system of claim 1, wherein the RF power supply is programmed to supply power during a pre-treatment phase in which a catalyst material is granularized.

15. The system of claim 1, wherein the RF power supply is programmed to supply power during a post-treatment phase.

16. The system of claim 1, wherein the DC power supply is configured to supply a negative voltage within a range of about 100 to about 1000 V.

17. The system of claim 1, wherein the RF power supply is configured to supply power within a range of about 0.5 to about 1.5 Watts/cm².

18. The system of claim 1, wherein the RF power supply has a frequency range of about 13.56 MHz to about 4 GHz.

19. The system of claim 1, wherein the DC and RF power supplies are each coupled to the electrode structure through a plurality of electrical contact points.

20. The system of claim 1, further comprising:
a pressure control subsystem for controlling the pressure within the chamber.

21. The system of claim 20, wherein the pressure control subsystem is capable of creating a pressure in the chamber within a range of about 0.1 to about 10 Torr.

22. A system for forming carbon nanotubes using plasma enhanced chemical vapor deposition (PECVD), the system comprising:
a means for supplying a source gas, the source gas including carbon for formation of carbon nanotubes onto a target;
a radio frequency (RF) means for applying energy to granularize a catalyst material on the target; and
a direct current (DC) means for applying energy to the received source gas sufficient to form carbon radicals or ions to cause synthesis of carbon nanotubes on the granularized catalyst material on the target.

23. The system of claim 22, further comprising:
means for heating the target.

24. The system of claim 22, further comprising:
means for controlling a pressure within the system.

25. A method for operating a plasma enhanced chemical vapor deposition (PECVD) system to form carbon nanotubes on a target substrate, the method comprising:
loading the target substrate in the PECVD system;
introducing a source gas within the PECVD system, the source gas including carbon for forming carbon nanotubes on the target substrate; and
applying a DC voltage to an electrode within the PECVD system, the applied DC voltage sufficient to disassociate the carbon in the source gas and cause synthesis of carbon nanotubes on the target substrate.

26. The method of claim 25, wherein the applied DC voltage is within a range of about −100 to about −1000 V.

27. The method of claim 25, further comprising:
before the synthesis of carbon nanotubes on the target substrate, applying power from a RF power supply to an electrode within the PECVD system, the applied power for granularizing a catalyst material on the target substrate.

28. The method of claim 27, wherein the applied power from the RF power supply is within a range of about 0.5 to about 1.5 Watts/cm².

29. The method of claim 27, wherein the applied power from the RF power supply has a frequency range of about 13.56 MHz to about 4 GHz.

30. The method of claim 25, further comprising:
heating the target substrate.

31. The method of claim 30, wherein the target substrate is heated to a temperature within a range of about 300 to about 600° C.

32. The method of claim 25, further comprising:
controlling the pressure within the PECVD system.

33. The method of claim 32, wherein the controlled pressure within the PECVD system within a range of about 0.1 to about 10 Torr.

34. In a system for forming carbon nanotubes using plasma enhanced chemical vapor deposition (PECVD), the system including a direct current (DC) power supply, a method for forming a plurality of carbon nanotubes comprising: applying a DC voltage to an electrode of the system with the DC power supply, the applied DC voltage sufficient without additional applied RF power to cause synthesis of carbon nanotubes on a substrate.
